(19) United States
(12) Patent Application Publication
(10) Pub. No.: US 2002/0148320 A1
(43) Pub. Date: Oct. 17, 2002

(54) Arms of scalar robot

(75) Inventors: Kazuo Kimata, Ichinomiya-shi (JP); Takao Nakamori, Ichinomiya-shi (JP); Katsuhiko Kato, Ichinomiya-shi (JP)

Correspondence Address: ARMSTRONG,WESTERMAN & HATTORI, LLP, 1725 K STREET, NW., SUITE 1000, WASHINGTON, DC, 20006, US

(73) Assignee: AITEC Corporation, Ichinomiya-shi (JP)

(21) Appl. No.: 10/117,200

(22) Filed: Apr. 8, 2002

(30) Foreign Application Priority Data
Apr. 11, 2001 (JP) 2001-112242

(51) Int. Cl. H01L 21/68

(52) U.S. Cl. 74/490.01

(57) ABSTRACT

A first arm 2 comprises a movable pulley 18 assembled and fixed in a hand 1, a fixed pulley 16 assembled and fixed in a second arm 3, and a timing belt 22 stretched between the movable pulley 18 and fixed pulley 16. A frame 19 has a plane shape corresponding to a virtual plane region enclosed by the timing belt 22. In the frame 19, a first fixed shaft 21 for rotatably holding the movable pulley 18 and a second fixed shaft 17 extending from the second arm 3 for assembling and fixing the fixed pulley 16 are assembled and fixed. An outer cover 60 is light in weight, and covers the frame 19.

### BACKGROUND OF THE INVENTION

(1) Field of the Invention

The present invention relates to arms of a scalar robot, and more particularly to arms of a scalar robot for conveying thin boards such as semiconductor substrates or glass substrates.

(2) Description of the Prior Art

FIG. 8 to FIG. 14 show a configuration of arms of a scalar robot in a prior art.

In FIG. 8 to FIG. 14, reference numeral 1 is a hand, 2 is a first arm, 3 is a second arm, and 4 is a bench. The bench is horizontally rotatable by a drive device not shown in the diagram.

The second arm 3 has a fixed pulley 5 at its base. The fixed pulley 5 is assembled and fixed in the bench 4 by means of a mounting bracket 6. In the central hole of the fixed pulley 5, a rotary shaft 7 extending upward from the bench 4 is rotatably inserted. The rotary shaft 7 is rotated normally and reversely by the drive device not shown. A frame 8 of the second arm 3 is assembled and fixed in the rotary shaft 7 by means of a mounting bracket 9. The second arm 3 has a movable pulley 10 provided at its leading end. The movable pulley 10 is rotatably held by a fixed shaft 12 assembled and fixed in the frame 8 by means of a mounting bracket 11. A timing belt 13 is stretched between the fixed pulley 5 and movable pulley 10. The tension of the timing belt 13 is adjusted by a tension pulley 15 assembled and fixed in the frame 8 by means of a mounting bracket 14.

The first arm 2 has a fixed pulley 16 at its base. The fixed pulley 16 is assembled and fixed in a fixed shaft (second fixed shaft) 17 extending upward from the leading end of the second arm 3. The first arm 2 has a movable pulley 18 provided at its leading end. The movable pulley 18 is rotatably held by a fixed shaft (first fixed shaft) 21 assembled and fixed in a frame 19 by means of a mounting bracket 20. A hand 1 is assembled and fixed in the movable pulley 18. A timing belt 22 is stretched between the fixed pulley 16 and movable pulley 18. The tension of the timing belt 22 is adjusted by a tension pulley 24 assembled and fixed in the frame 19 by means of a mounting bracket 23. In the diagram, reference numeral 25 is an electric wiring of air tube and sensor for vacuum suction.

In the scalar robot having such arms 2, 3, as known well, the second arm 3 and the first arm 2 oscillate horizontally and the hand 1 reciprocates on a horizontal linear track by rotating the motor of the drive device (not shown) inside of the bench 4 in normal and reverse directions.

In the conventional arms 2, 3, however, the frames 8, 19 also serve as outer covers, and the frames 8, 19 have enough wall thickness to function as frames capable of assembling and fixing each type of parts, and formed in the entire circumference of the side surface and whole area of the upper surface (except for the leading end and the base) in order to function as outer covers for covering the parts. Accordingly, there have been problems that the frames 8, 19 are heavy, and the weight of the arms 2, 3 or the entire robot is increased, and the conveying speed of the robot is limited, and the inertia is large, and dynamic deflection is likely to occur, or the like.

### 3. SUMMARY OF THE INVENTION

It is hence an object of the present invention to provide arms based on a novel concept, capable of reducing the weight of the arms, increasing the conveying speed, and suppressing dynamic deflection, by solving the problems of the conventional arms.

The first arm of a scalar robot of the present invention is a first arm of scalar robot disposed between a hand and a second arm, which comprises a movable pulley assembled and fixed in the hand, a fixed pulley assembled and fixed in the second arm, a timing belt stretched between the movable pulley and fixed pulley, a frame having a plane shape corresponding to a virtual plane region enclosed by the timing belt, with a first fixed shaft for rotatably holding the movable pulley and a second fixed shaft extending from the second arm for assembling and fixing the fixed pulley, being assembled and fixed in this frame, and an outer cover of light weight for covering the frame.

The second arm of a scalar robot of the present invention is a second arm of a scalar robot disposed between a first arm and a bench, which comprises a movable pulley assembled and fixed in the first arm, a fixed pulley assembled and fixed in the bench, a timing belt stretched between the movable pulley and fixed pulley, a frame having a plane shape corresponding to a virtual plane region enclosed by the timing belt, with a fixed shaft for rotatably holding the movable pulley and a rotary shaft extending from the bench to be rotatably inserted in a central hole of the fixed pulley, being assembled and fixed in this frame, and an outer cover of light weight for covering the frame.

Here, a tension pulley mounting portion is integrally formed in the frame.

Further, the outer cover is preferably made of a synthetic resin material or a thin metal material.

Preferably, the frame and outer cover are individually divided and coupled toward the arm length direction.

Alternatively, the frame and outer cover are individually integrated toward the arm length direction.

The arms of a scalar robot of the present invention comprise frames for assembling each type of parts, and outer covers of light weight for covering the frames assembling the parts.

### 4. BRIEF DESCRIPTION OF THE DRAWINGS

FIG. 1 is a vertical sectional view along the arm length direction of first and second arms of a scalar robot according to an embodiment of the present invention.

FIG. 2 is a plan view of the first arm showing a state that the upper cover is removed.

FIG. 3 is a bottom view of the first arm showing a state that the bottom cover is removed.

FIG. 4 is a vertical sectional view of the first arm along the arm width direction.

FIG. 5 is a plan of the second arm showing a state that the upper cover is removed.

FIG. 6 is a bottom view of the second arm showing a state that the bottom cover is removed.

FIG. 7 is a vertical sectional view of the second arm along the arm width direction.

FIG. 8 is a vertical sectional view along the arm length direction of first and second arms of a scalar robot according to a prior art.

FIG. 9 is a plan view of the first arm.

FIG. 10 is a bottom view of the first arm showing a state that the bottom cover is removed.

FIG. 11 is a vertical sectional view of the first arm along the arm width direction.

FIG. 12 is a plan view of the second arm.

FIG. 13 is a bottom view of the second arm showing a state that the bottom cover is removed.

FIG. 14 is a vertical sectional view of the second arm along the arm width direction.

### 5. DESCRIPTION OF THE PREFERRED EMBODIMENTS

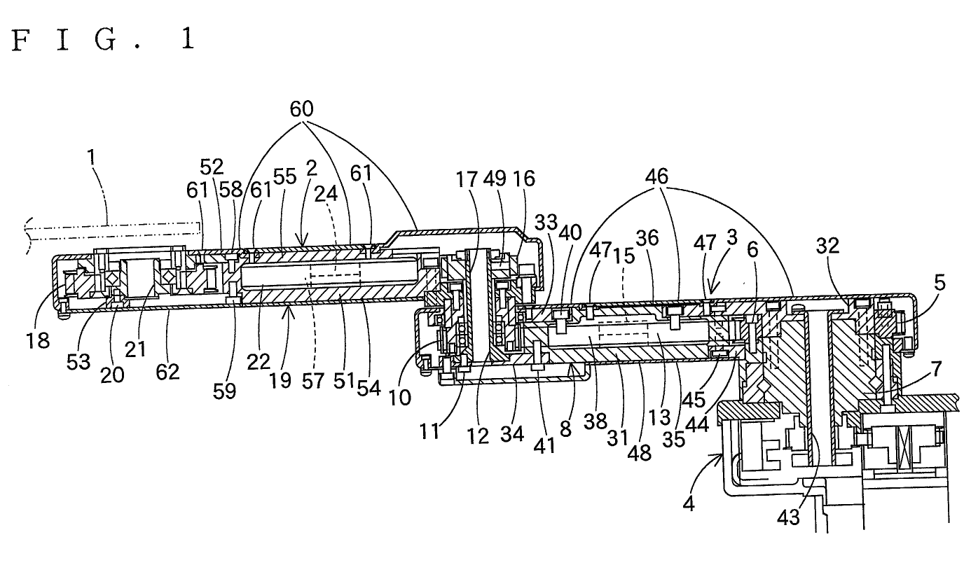

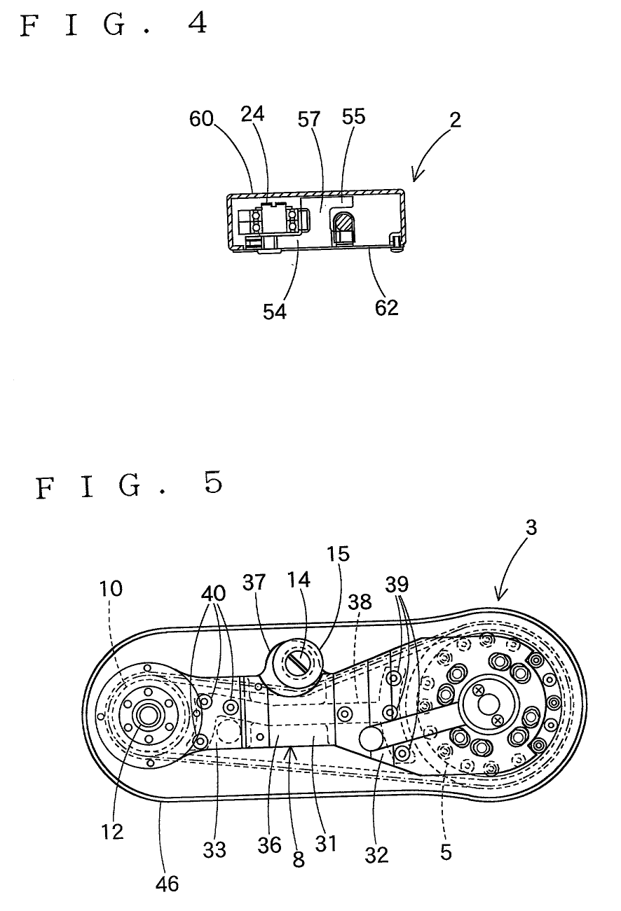

In FIG. 1 to FIG. 7, reference numeral 1 is a hand, 2 is a first arm, 3 is a second arm, and 4 is a bench. The bench is horizontally rotatable by a drive device not shown in the diagram.

1) Second arm 3

The second arm 3 has a fixed pulley 5 at its base. The fixed pulley 5 is assembled and fixed in the bench 4 by means of a mounting bracket 6. In the central hole of the fixed pulley 5, a rotary shaft 7 extending upward from the bench 4 is rotatably inserted. The rotary shaft 7 is rotated normally and reversely by the drive device not shown. The second arm 3 has a movable pulley 10 provided at its leading end. The movable pulley 10 is rotatably held by a fixed shaft 12. The fixed shaft 12 is assembled and fixed in a frame 8 by means of a mounting bracket 11. A timing belt 13 is stretched between the fixed pulley 5 and movable pulley 10. The tension of the timing belt 13 is adjusted by a tension pulley 15. The tension pulley 15 is assembled and fixed in the frame 8 by means of a mounting bracket 14.

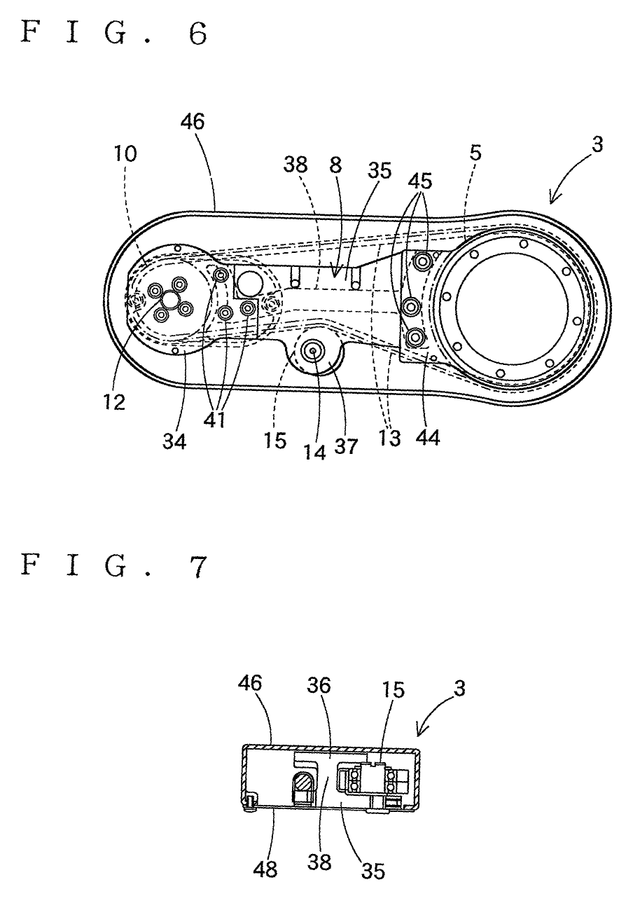

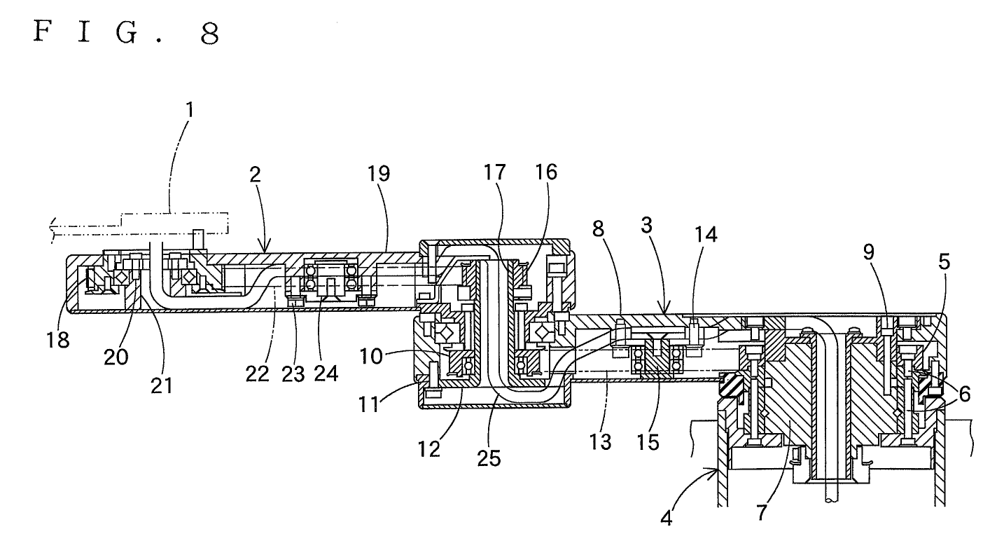

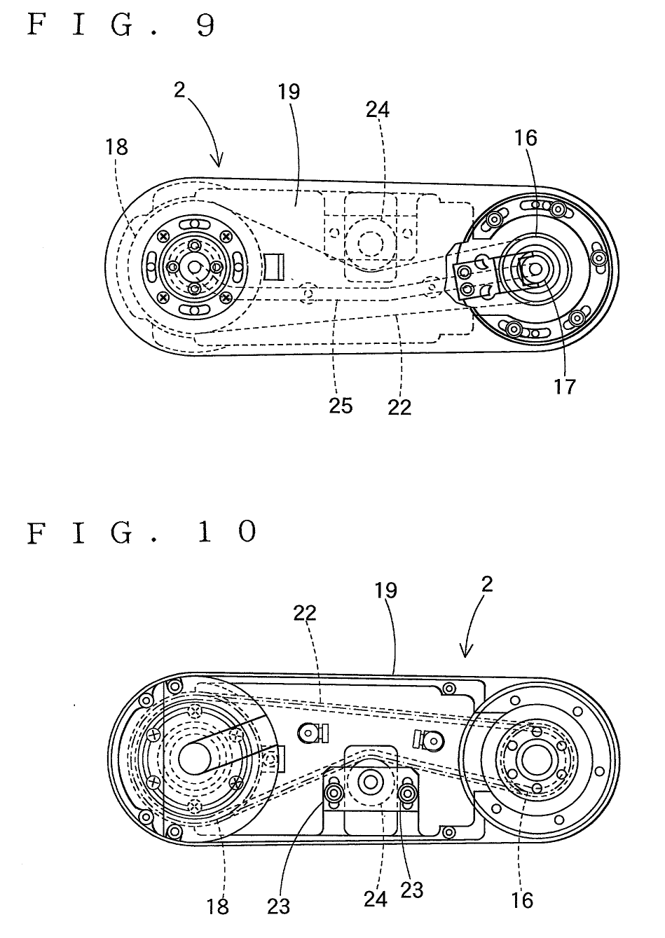

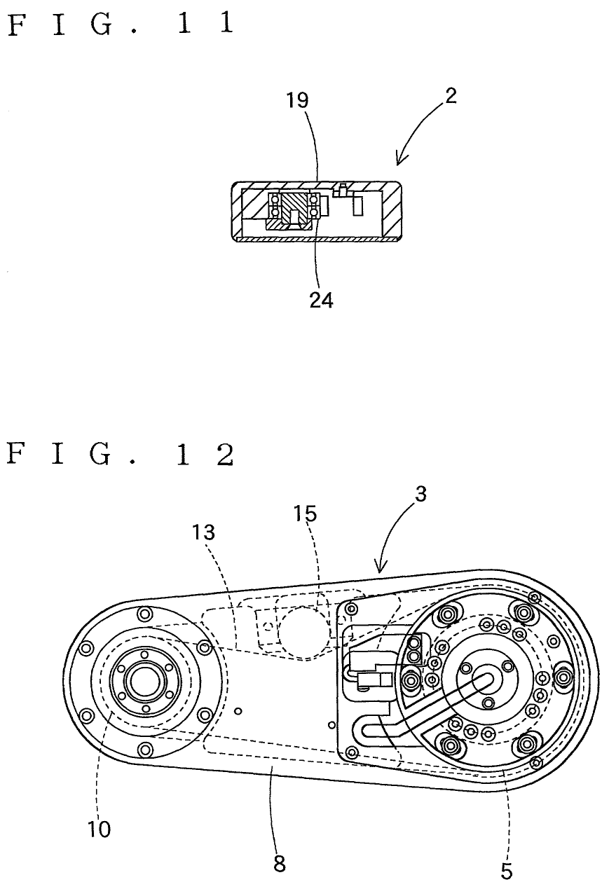

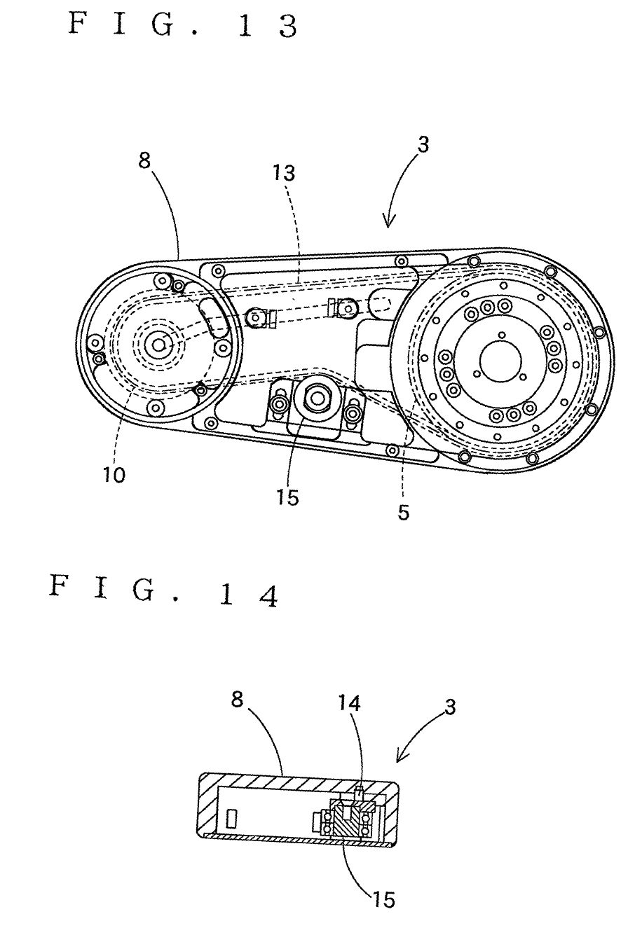

The frame 8 has a plane shape corresponding to a virtual plane region enclosed by the timing belt 13 as shown in FIG. 5 and FIG. 6. The frame 8 is composed of and divided into a base frame 31 positioned in the central part in the arm length direction, a bench side upper frame 32 assembled and fixed on the top of the side end of the bench 4 of the base frame 31, a first arm side upper frame 33 assembled and fixed on the top of the side end of the first arm 2 of the base frame 31, and a first arm side lower frame 34 assembled and fixed on the lower surface of the side end of the first arm 2 of the base frame 31. The base frame 31 has a bottom plate 35 and a top plate 36. The bottom plate 35 comprises a tension pulley mounting portion 37 for assembling and fixing the tension pulley 15. A vertical wall 38 is integrally formed between the bottom plate 35 and top plate 36. The vertical wall 38 is formed, as shown in FIG. 5 and FIG. 6, with width enough for assembling and fixing the bench side upper frame 32, first arm side upper frame 33, and first arm side lower frame 34 on the base frame 31 from above to beneath by means of mounting brackets 39, 40, 41, respectively, so that the weight is reduced. The bench side upper frame 32 is assembled and fixed to the top of the bench 4 side of the vertical wall 38 by the mounting bracket 39, and the bench side upper frame 32 is also assembled and fixed on the top of the rotary shaft 7 by means of a mounting bracket 42. The bench side upper frame 32 has a penetration hole in the vertical direction. In this penetration hole, a hollow cylindrical member 43 for passing an air tube and an electric wiring is fixed and disposed. At the lower side of the bench 4 side of the vertical wall 38, a seal member 44 is assembled and fixed by a mounting bracket 45. The seal member 44 has a penetration hole in the vertical direction in which the rotary shaft 7 and others are inserted. The first arm side upper frame 33 is assembled and fixed on the top of the first arm 2 side of the vertical wall 38 by the mounting bracket 40. The first arm side upper frame 33 has a penetration hole in the vertical direction. In this penetration hole, the movable pulley 10 is rotatably inserted. The first arm side lower frame 34 is assembled and fixed on the lower surface of the first arm 2 side of the vertical wall 38 by the mounting bracket 41. The first arm side lower frame 34 is integrated with the hollow cylindrical member (fixed shaft) 12. The hollow cylindrical member (fixed shaft) 12 holds the movable pulley 10 rotatably, and passes the air tube and electrical wiring.

As described herein, the frame 8 is divided and coupled in the arm length direction. Accordingly, by preparing plural base frames 31 different in length at every arm length, and selecting a proper base frame 31 suited to the arm length, plural second arms 3 different in length can be assembled easily.

On the top of the frame 8, an upper cover (outer cover) 46 is divided and coupled in the arm length direction same as the frame 8, and is assembled and fixed by a mounting bracket 47. The upper cover 46 covers the entire area of the top (excluding above the movable pulley) and the entire area of the side. The upper cover 46 is composed of a synthetic resin material or a thin metal material, and is reduced in weight.

At the lower side of the frame 8, a bottom cover 48 is assembled and fixed. The bottom cover 48 is made of, for example, an aluminum material.

2) First arm 2

The first arm 2 has a fixed pulley 16 at its base. The fixed pulley 16 is assembled and fixed by means of a mounting bracket 49 in a fixed shaft (second fixed shaft) 17 extending from the second arm 3. The first arm 2 has a movable pulley 18 provided at its leading end. The movable pulley 18 is rotatably held by a fixed shaft (first fixed shaft) 21. The first fixed shaft 21 is assembled and fixed in a frame 19 by means of a mounting bracket 20. A timing belt 22 is stretched between the fixed pulley 16 and movable pulley 18. The tension of the timing belt 22 is adjusted by a tension pulley 24. The tension pulley 24 is assembled and fixed in the frame 19 by means of a mounting bracket 23.

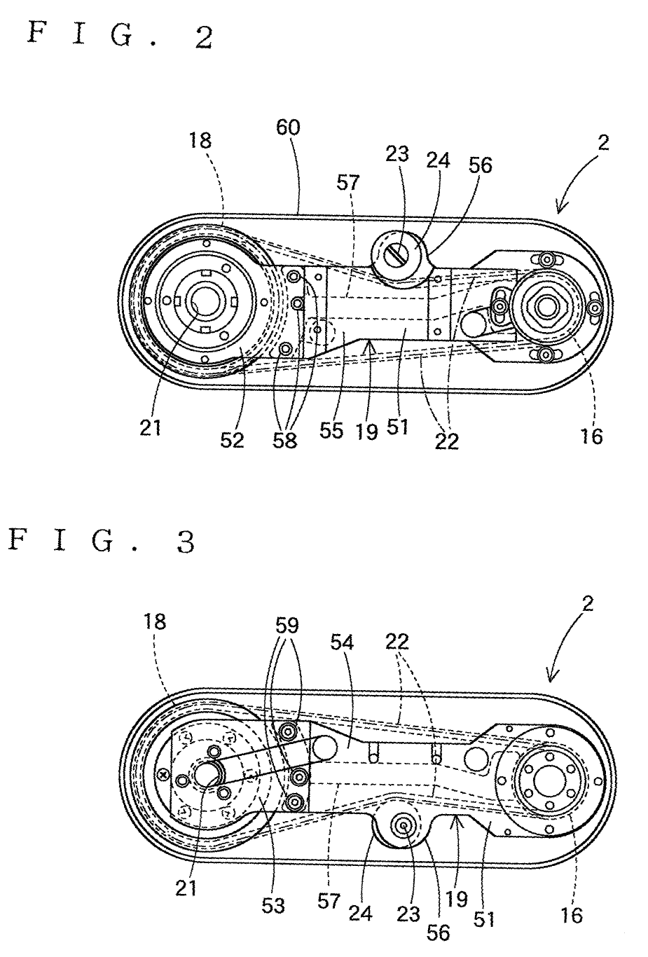

The frame 19 has a plane shape corresponding to a virtual plane region enclosed by the timing belt 22 as shown in FIG. 2 and FIG. 3. The frame 19 is composed of and divided into a base frame 51 positioned at the second arm side from the central part in the arm length direction, a hand side upper frame 52 assembled and fixed on the top of the side end of the hand 1 of the base frame 51, and a hand side lower frame 53 assembled and fixed on the lower surface of the side end of the hand 1 of the base frame 51. The base frame 51 has a bottom plate 54 and a top plate 55. The bottom plate 54 comprises a tension pulley mounting portion 56 for assembling and fixing the tension pulley 24. A vertical wall 57 is integrally formed between the bottom plate 54 and top plate 55. The vertical wall 57 is formed, as shown in FIG. 2 and FIG. 3, with enough width for assembling and fixing the hand side upper frame 52 and hand side lower frame 53 on the base frame 51 from above to beneath by means of mounting brackets 58 and 59, respectively, so that the weight is reduced. The hand side upper frame 52 is assembled and fixed to the top of the hand 1 side of the vertical wall 57 by the mounting bracket 58. The hand side upper frame 52 has a penetration hole in the vertical direction. In this penetration hole, the movable pulley 18 is rotatably inserted. The hand side lower frame 53 is assembled and fixed on the lower surface of the hand 1 side of the vertical wall 57 by the mounting bracket 59. The hand side lower frame 53 is integrated with the hollow cylindrical member (first fixed shaft) 21. The first fixed shaft 21 holds the movable pulley 18 rotatably, and passes the air tube and electrical wiring.

As described herein, the frame 19 is divided and coupled in the arm length direction. Accordingly, by preparing plural base frames 51 different in length at every arm length, and selecting a proper base frame 51 suited to the arm length, plural first arms 2 different in the arm length can be assembled easily.

On the top of the frame 19, an upper cover (outer cover) 60 is divided and coupled in the arm length direction same as the frame 19, and is assembled and fixed by a mounting bracket 61. The upper cover 60 covers the entire area of the top (excluding above the movable pulley) and the entire area of the side. The upper cover 60 is composed of a synthetic resin material or a thin metal material, and is reduced in weight.

At the lower side of the frame 19, a bottom cover 62 is assembled and fixed. The bottom cover 62 is made of, for example, an aluminum material.

In the scalar robot having such arms 2, 3, as known well, by rotating normally and reversely the motor of the drive device (not shown) in the bench 4, the second arm 3 and first arm 2 oscillates horizontally, and the hand 1 reciprocates on a horizontal linear track.

As explained herein, the first arm 2 of the scalar robot according to the embodiment is the first arm 2 of the scalar robot disposed between the hand 1 and the second arm 3, which comprises the movable pulley 18 assembled and fixed in the hand 1, the fixed pulley 16 assembled and fixed in the second arm 3, and the timing belt 22 stretched between the movable pulley 18 and fixed pulley 16, and in this first arm 2, the frame 19 has a plane shape corresponding to a virtual plane region enclosed by the timing belt 22, and it further comprises the frame 19 in which the first fixed shaft 21 for rotatably holding the movable pulley 18 and the second fixed shaft 17 extending from the second arm 3 for assembling and fixing the fixed pulley 16 are assembled and fixed, and also the outer cover 60 of light weight for covering the frame 19. Accordingly, since the first arm 2 is reduced in weight, the conveying speed is increased and dynamic deflection is suppressed.

The second arm 3 of the scalar robot according to the embodiment is the second arm 3 of the scalar robot disposed between the first arm 2 and the bench 4, which comprises the movable pulley 10 assembled and fixed in the first arm 2, the fixed pulley 5 assembled and fixed in the bench 4, and the timing belt 13 stretched between the movable pulley 10 and fixed pulley 5, and in this second arm 3, the frame 8 has a plane shape corresponding to a virtual plane region enclosed by the timing belt 13, and it further comprises the frame 8 in which the fixed shaft 12 for rotatably holding the movable pulley 10 and the rotary shaft 7 extending from the bench 4 to be rotatably inserted in a central hole of the fixed pulley 5 are assembled and fixed, and also the outer cover 46 of light weight for covering the frame 8. Accordingly, since the second arm 3 is reduced in weight, the conveying speed is increased and dynamic deflection is suppressed.

Further, since the tension pulley mounting portion 37, 56 is integrally formed in the frame 8, 19, the number of parts can be curtailed.

Moreover, since the outer cover 46, 60 is made of a synthetic resin material or a thin metal material, and it easy to form.

Also, since the frame 8, 19 and outer cover 46, 60 are individually divided and coupled toward the arm length direction, it is easy to cope with flexibly for arms different in arm length.

Still more, the frame 8, 19 and outer cover 46, 60 may be individually integrated toward the arm length direction.

1. A first arm of scalar robot disposed between a hand and a second arm, comprising:
a movable pulley assembled and fixed in said hand,
a fixed pulley assembled and fixed in said second arm,
a timing belt stretched between said movable pulley and fixed pulley,
a frame having a plane shape corresponding to a virtual plane region enclosed by said timing belt, with a first fixed shaft for rotatably holding said movable pulley and a second fixed shaft extending from said second arm for assembling and fixing said fixed pulley, being assembled and fixed in this frame, and
an outer cover of light weight for covering said frame.

2. A second arm of scalar robot disposed between a first arm and a bench, comprising:
a movable pulley assembled and fixed in said first arm,
a fixed pulley assembled and fixed in said bench,
a timing belt stretched between said movable pulley and fixed pulley,
a frame having a plane shape corresponding to a virtual plane region enclosed by said timing belt, with a fixed shaft for rotatably holding said movable pulley and a rotary shaft extending from said bench to be rotatably inserted in a central hole of said fixed pulley, being assembled and fixed in this frame, and
an outer cover of light weight for covering said frame.

3. The arms of scalar robot of claim 1 or 2, wherein a tension pulley mounting portion is integrally formed in said frame.

4. The arms of scalar robot of claim 1 or 2, wherein said outer cover is made of a synthetic resin material.

5. The arms of scalar robot of claim 1 or 2, wherein a tension pulley mounting portion is integrally formed in said frame, and said outer cover is made of a synthetic resin material.

6. The arms of scalar robot of claim 1 or 2, wherein said outer cover is made of a thin metal material.

7. The arms of scalar robot of claim 1 or 2, wherein a tension pulley mounting portion is integrally formed in said frame, and said outer cover is made of a thin metal material.

8. The arms of scalar robot of claim 1 or 2, wherein said frame and outer cover are individually divided and coupled toward the arm length direction.

9. The arms of scalar robot of claim 3, wherein said frame and outer cover are individually divided and coupled toward the arm length direction.

10. The arms of scalar robot of claim 4, wherein said frame and outer cover are individually divided and coupled toward the arm length direction.

11. The arms of scalar robot of claim 5, wherein said frame and outer cover are individually divided and coupled toward the arm length direction.

12. The arms of scalar robot of claim 6, wherein said frame and outer cover are individually divided and coupled toward the arm length direction.

13. The arms of scalar robot of claim 7, wherein said frame and outer cover are individually divided and coupled toward the arm length direction.

14. The arms of scalar robot of claim 1 or 2, wherein said frame and outer cover are individually integrated toward the arm length direction.

15. The arms of scalar robot of claim 3, wherein said frame and outer cover are individually integrated toward the arm length direction.

16. The arms of scalar robot of claim 4, wherein said frame and outer cover are individually integrated toward the arm length direction.

17. The arms of scalar robot of claim 5, wherein said frame and outer cover are individually integrated toward the arm length direction.

18. The arms of scalar robot of claim 6, wherein said frame and outer cover are individually integrated toward the arm length direction.

19. The arms of scalar robot of claim 7, wherein said frame and outer cover are individually integrated toward the arm length direction.

20. Arms of scalar robot comprising frames for assembling each type of parts, and outer covers of light weight for covering the frames assembling said each type of parts.
